(19) United States
(12) Patent Application Publication
(10) Pub. No.: US 2006/0232703 A1
(43) Pub. Date: Oct. 19, 2006

(54) Picture display device

(75) Inventor: Yoshimi Enomoto, Kashiwa-shi, Chiba (JP)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., 5621 BA Eindhoven (NL)

(21) Appl. No.: 10/568,368

(22) PCT Filed: Aug. 13, 2004
(86) PCT No.: PCT/IB04/51457

§ 371 Date: Feb. 14, 2006

(30) Foreign Application Priority Data
Aug. 18, 2003 (IB) 03/03667

(51) Int. Cl. H04N 11/20; H03M 1/12

(52) U.S. Cl. 348/445; 348/572

(57) ABSTRACT

When a user instructs non-linear process, controlling means (19) sends a control signal indicating the non-linear process to a clock change instruction means (183) of a display converting means (18). If the clock change instruction means (183) receives the control signal, the means (183) sends an instruction for a variable clock to clock generating means (185) and difference calculating means (184). The clock generating means (185) generates a variable clock in response to the instruction of the clock change instruction means (183) and outputs it to A/D converter (11). The clock generating means (185) generates a constant frequency clock and outputs it to a data smoothing means (12). The difference calculating means (184) calculates a difference between the variable clock and the constant frequency clock generated in the clock generating means (185) in response to the instruction of the clock change instruction means (183), and outputs the difference information to a luminance signal extracting means (13), an edge enhancement means (15) and a chroma decoding means (16).

### TECHNICAL FIELD

The present invention relates to a picture display device, in particular to a picture display device performing a non-linear displaying of an analogue picture signal.

### BACKGROUND ART

One example of a picture display device for displaying a received analogue picture signal is shown in FIG. 1. FIG. 1 is a block diagram diagrammatically showing an arrangement of a conventional picture display device. Here, an analogue picture signal is an analogue composite picture signal resulting from modulation and multiplexing of a luminance signal and a chroma signal (color signal).

The received analogue picture signal is sent to an analog/digital (A/D) conversion means 1 where the signal is A/D converted. The A/D converted signal is outputted to a luminance signal extracting means 2 and a chroma signal extracting means 3.

The luminance signal extracting means 2 removes the chroma signal using a field and line correlation specific to a composite signal system and extracts only the luminance signal. The extracted luminance signal is outputted to an edge enhancement means 4.

On the other hand, the chroma signal extracting means 3 likewise removes the luminance signal using a field and line correlation specific to the composite signal system and extracts only the chroma signal. The extracted chroma signal is outputted to a chroma decoding means 5.

The edge enhancement means 4 performs process for enhancing picture edges using the luminance signal to increase sharpness of the picture. The signal subjected to the edge enhancement process is outputted to a format means 6. The chroma decoding means 5 decodes the chroma signal into a baseband signal and outputs the decoded signal to the format means 6.

The format means 6 changes the picture size to a screen size suitable for a display device using the luminance signal and color signal, and outputs this size-changed picture signal to a display converting means 7. The display converting means 7 converts the picture signal to a specific picture signal with a specific signal format suitable for the display device. Then, the specific picture signal is outputted to the display device for display.

Note that the change of the picture size at the format means 6 and conversion to the specific picture signal at the display converting means 7 are performed under the control of a controlling means 8.

Current picture display devices tend to have wider screens to support digital broadcasting, etc. When a conventional analogue picture signal is displayed on this wide screen, the analogue picture signal is subjected to a panoramic simultaneous process in horizontal direction and subjected to non-linear displaying (process of converting an analogue picture signal with an aspect ratio of 4:3 to a picture signal with an aspect ratio of 16:9).

When an ordinary analogue picture signal is displayed on a wide screen with its aspect signal being kept, a picture display area 21a and a non-picture display area 21b called ‘side panel’ are formed as shown in FIG. 2(a). When this analogue picture signal is subjected to a panoramic simultaneous process and non-linear displaying, the result appears like FIG. 2 (b). At this moment, instead of extending the analogue picture signal uniformly in horizontal direction, a process of extending only the side part 22b with the central part 22a unchanged. This process is performed by changing a scanning rate depending on the display position of the display device.

When the picture display device in the above described structure performs panoramic simultaneous process in the horizontal direction and non-linear displaying, the scanning rate is changed according to the display position of the display device, and therefore the picture display device needs to perform time conversion process. Performing this time conversion process involves a problem that the circuit size becomes large. Moreover, while the scanning rate is variable, the sampling rate is always constant, and therefore the display quality varies depending on the display position substantially, that is, the quality of the side part 22b degrades.

### DISCLOSURE OF INVENTION

It is an object of the present invention to provide a picture display device whose circuit size does not become large and whose display quality does not degrade even if panoramic non-linear displaying is performed.

Noticing the fact that when a panoramic simultaneous process in horizontal direction and non-linear displaying are performed, the sampling rate is always constant though the scanning rate is variable, the present inventor has come up with the present invention by discovering that it is possible to prevent the display quality from degrading and eliminate the need of time conversion process by making sampling var iable according to the scanning rate.

That is, an essence of the present invention is to prevent the display quality from degrading and eliminate the need for time conversion process to display the picture by generating a variable clock for changing the sampling rate of an analogue picture signal according to the scanning rate when the analogue picture signal is displayed on a display device, performing sampling based on the variable clock, A/D converting the analogue picture signal, separating the A/D converted picture signal into a luminance signal and a chroma signal, performing edge enhancement process on the luminance signal, decoding the chroma signal and performing signal format conversion for the display device by using the luminance signal and a decoded color signal.

A picture display device according to the invention for displaying a picture by using an analogue picture signal including a luminance signal and a chroma signal is characterized by comprising clock generating means for generating a variable clock for changing a sampling rate of the analogue picture signal depending on a scanning rate in displaying the analogue picture signal on a display device, an A/D converter for A/D converting the analogue picture signal by sampling with the variable clock, signal separating means for separating the A/D converted picture signal into the luminance signal and the chroma signal, decoding means for decoding the chroma signal and signal format converting means for converting the luminance signal and the decoded color signal into signals with a signal format for the display device.

In the picture display device according to the invention, the clock generating means preferably generates a constant frequency clock and further comprises smoothing means for smoothing the A/D converted picture signal using the constant frequency clock.

The picture display device according to the invention preferably further comprises difference calculating means for obtaining difference information between the variable clock and the constant frequency clock generated by the clock generating means.

The picture display device according to the invention preferably further comprises edge enhancement means for performing edge enhancement process to the luminance signal.

In the picture display device according to the invention, the signal separating means, the edge enhancement means and the decoding means preferably perform signal separating process, edge enhancement process and decoding process using the difference information respectively.

The picture display device according to the invention preferably further comprises screen size recognition means for recognizing a screen size of the analogue picture signal from the analogue picture signal.

In the picture display device according to the invention, non-linear display in the horizontal direction is preferably performed by changing a sampling rate of the analogue picture signal depending on a scanning rate in displaying the analogue picture signal on a display device.

In the picture display device according to the invention, the display device is preferably a device selected from a group of a liquid crystal display device, plasma display device and electro-luminescence display device.

### DESCRIPTION OF DRAWINGS

FIG. 1 is a block diagram diagrammatically showing an arrangement of a conventional picture display device;

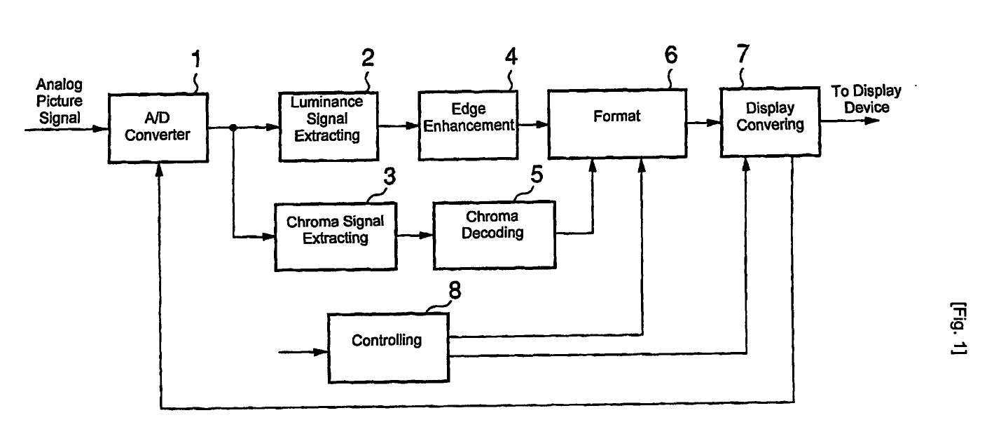

FIGS. 2a and 2b show displayed pictures for explaining a screen size conversion by a non-linear process;

FIG. 3 is a block diagram diagrammatically showing an arrangement of a picture display device according to an Embodiment of the present invention;

FIG. 4 is a block diagram diagrammatically showing an arrangement of the display converting means of the picture display device shown in FIG. 3; and

FIG. 5 shows a timing chart of a variable clock and a constant frequency clock outputted from the display converting means shown in FIG. 4.

### BEST MODE

With reference now to the attached drawings, an embodiment of the present invention will be explained in detail below.

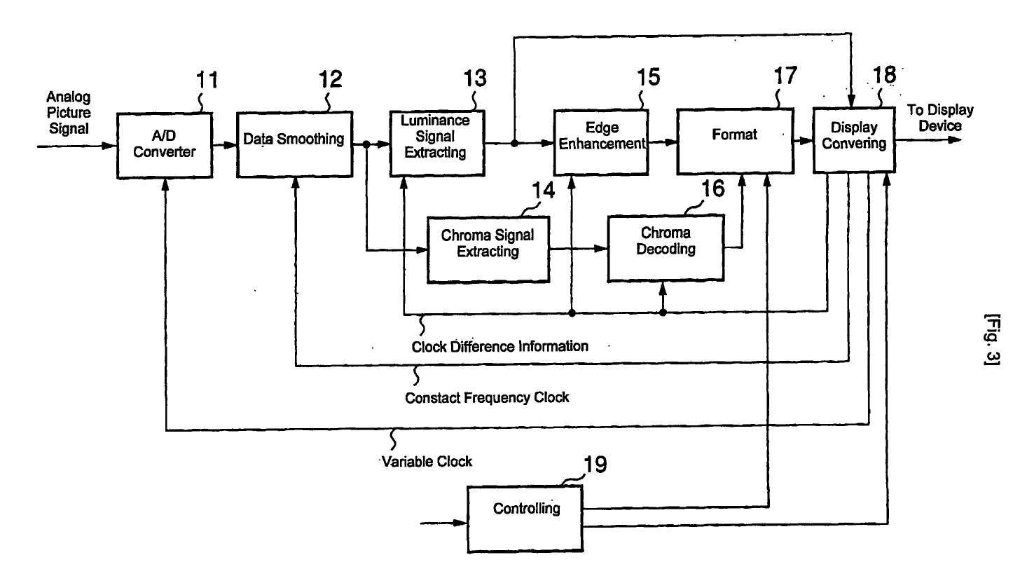

FIG. 3 is a block diagram diagrammatically showing an arrangement of a picture display device according to an Embodiment of the present invention. Here, the analogue picture signal is an analog composite picture signal resulting from multiplexing of a luminance signal and a chroma signal.

A received analogue picture signal is sent to an analog/digital (A/D) conversion means 11 where the signal is A/D converted. The A/D converter 11 performs sampling on a clock outputted from a display converting means 18 which will be described later. For example, when a non-linear displaying process is performed, sampling is performed on a variable clock and when a linear displaying process is performed, sampling is performed with a constant frequency clock. Performing sampling using a variable clock makes it possible to respond to a variable scanning rate without using time conversion process. The A/D converted signal is outputted to a data smoothing means 12.

The data smoothing means 12 smoothes the signal with a constant frequency clock corresponding to an input picture format outputted from the display converting means 18 which will be described later. Performing this data smoothing allows nonlinear data process at a constant rate in subsequent processes. The information on the input picture format may be given to the display converting means 18 beforehand or may be included in the received signal. The smoothed signal is outputted to a luminance signal extracting means 13 and a chroma signal extracting means 14.

The luminance signal extracting means 13 removes the chroma signal by using a field and line correlation specific to a composite signal structure and extracts only the luminance signal. More specifically, the luminance signal extracting means 13 removes a signal of 3.58 MHz component which is a color signal subcarrier frequency from the analogue picture signal and extracts the luminance signal. At the same time, the luminance signal extracting means 13 changes the cutoff frequency of a low pass filter of the picture according to clock difference information (information on the difference between the constant frequency clock and variable clock for sampling) from the display converting means 18 which will be described later. The extracted luminance signal is outputted to an edge enhancement means 15.

The chroma signal extracting means 14 removes the luminance signal by using a field and line correlation specific to the composite signal structure and extracts only the chroma signal. More specifically, the chroma signal extracting means 14 extracts a signal of 3.58 MHz component which is a color signal subcarrier frequency from the analogue picture signal and obtains the chroma signal. The extracted chroma signal is outputted to a chroma decoding means 16.

The edge enhancement means 15 performs a process for enhancing picture edges using the luminance signal to increase sharpness of the picture. At this time, the edge enhancement means 15 changes parameters in the edge enhancement process according to clock difference information from the display converting means 18 which will be described later. The signal subjected to the edge enhancement process is outputted to a format means 17.

The chroma decoding means 16 decodes the chroma signal into a baseband signal and outputs the decoded signal to the format means 17. At this time, the chroma decoding means 16 uses the clock difference information from the display converting means 18 which will be described later in the decoding process. This causes the chroma modulation reference frequency of the chroma signal which has been frequency-converted on the time axis to be reproduced stably, which allows stable chroma decoding.

The format means 17 changes the picture size to a screen size suitable for a display device by using the luminance signal and the color signal and outputs this size-changed picture signal to the display converting means 18.

The display converting means 18 converts the picture signal to a specific picture signal with a specific signal format suitable for the display device. That is, the display converting means 18 performs display conversion on the picture signal such as regular display, so-called letter box display and panoramic non-linear display.

Note that the change of the picture screen size at the format means 17 and the conversion to the specific signal format at the display converting means 18 are performed under the control of a controlling means 19. This controlling means 19 is designed to receive input information from the user and it is also possible to change the picture screen size based on the input information. Furthermore, it is also possible to perform a panoramic nonlinear process based on user's input information.

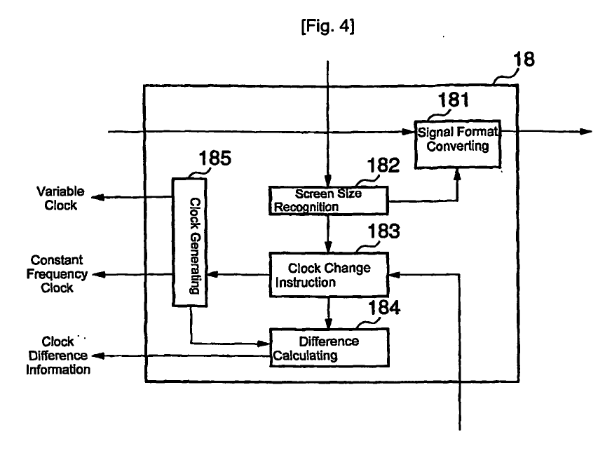

As shown in FIG. 4, the display converting means 18 is mainly constructed of a signal format converting means 181 that converts a picture signal to a signal format suitable for a display device, a screen size recognition means 182 that recognizes the screen size for display, a clock change instruction means 183 that gives an instruction to change a clock according to the screen size, a difference calculating means 184 that calculates a difference between a variable clock and a constant frequency clock and a clock generating means 185 that generates a variable clock and a constant frequency clock.

The signal format converting means 181 converts a picture signal from the format means 17 to a signal format suitable for a display device. This converted picture signal is sent to a display device such as an LCD or PDP and displayed as a picture on the display device.

The screen size recognition means 182 recognizes the screen size from the received signal. That is, when the screen size recognition means 182 receives an analogue picture signal with an aspect ratio of 4:3 and automatically performs panoramic non-linear display, the screen size recognition means 182 recognizes the screen size (aspect ratio 4:3) from the signal outputted from the luminance signal extracting means 13. For example, the screen size recognition means 182 recognizes the screen size by judging whether the analogue picture signal is a signal including a non-display area such as a letter box or full-screen signal.

In this way, the screen size recognition means 182 decides whether process for non-linear displaying is necessary or not. For example, when the screen size is 4:3, the process for non-linear displaying is necessary and when the screen size is 16:9, the process for non-linear displaying is not necessary. The information on this screen size is sent to the clock change instruction means 183.

The clock change instruction means 183 gives an instruction for changing a sampling clock for A/D conversion in the non-linear displaying process based on the screen size information from the screen size recognition means 182 or the user's instruction on a change of the screen size. The clock change instruction means 183 outputs an instruction for making the clock variable to the clock generating means 185. Furthermore, the instruction on the variable clock is also outputted to the difference calculating means 184.

The clock generating means 185 generates a constant frequency clock and a variable clock and outputs the clocks to the A/D converter 11 and data smoothing means 12. The clock generating means 185 generates a variable clock when it receives an instruction for making the clock variable from the clock change instruction means 183 and outputs the variable clock to the A/D converter 11. On the other hand, when no instruction for making the clock variable is received from the clock change instruction means 183, the clock generating means 185 generates a constant frequency clock and outputs the constant frequency clock to the A/D converter 11. Here, a clock corresponding to an input picture format is generated as the constant frequency clock outputted to the data smoothing means 12.

When it receives an instruction for making the clock variable from the clock change instruction means 183, the difference calculating means 184 calculates a difference between the variable clock and the constant frequency clock and outputs the difference information to the luminance signal extracting means 13, the edge enhancement means 15 and the chroma decoding means 16.

Next, a case where the picture display device in the above described structure performs a panoramic non-linear displaying process on an analogue picture signal will be explained.

Panoramic non-linear display can be performed by an instruction from the user or automatically performed by the apparatus. First, a case where panoramic non-linear display is performed by an instruction from the user will be explained.

When the user instructs non-linear display, that is, when the user gives an instruction to the controlling means 19, the controlling means 19 sends a control signal indicating non-linear displaying to the clock change instruction means 183 of the display converting means 18. When it receives the control signal, the clock change instruction means 183 gives an instruction for making the clock variable to the clock generating means 185 and the difference calculating means 184.

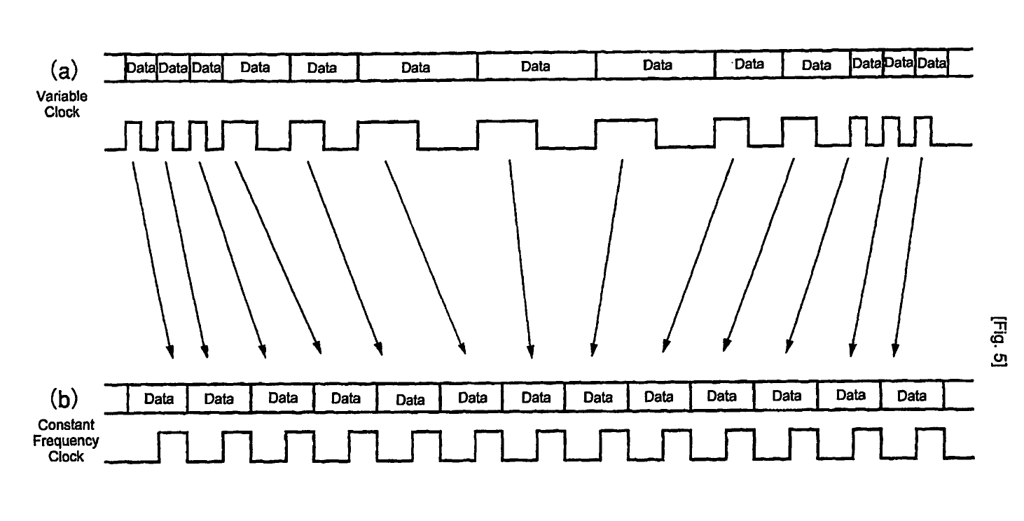

In response to the instruction from the clock change instruction means 183, the clock generating means 185 generates a variable clock shown in FIG. 5(a) and outputs this clock to the A/D converter 11. Furthermore, the clock generating means 185 generates a constant frequency clock shown in FIG. 5(b) and outputs this constant frequency clock to the data smoothing means 12.

The difference calculating means 184 calculates a difference between the variable clock generated and the constant frequency clock at the clock generating means 185 according to the instruction of the clock change instruction means 183 and outputs the difference information to the luminance signal extracting means 13, the edge enhancement means 15 and the chroma decoding means 16.

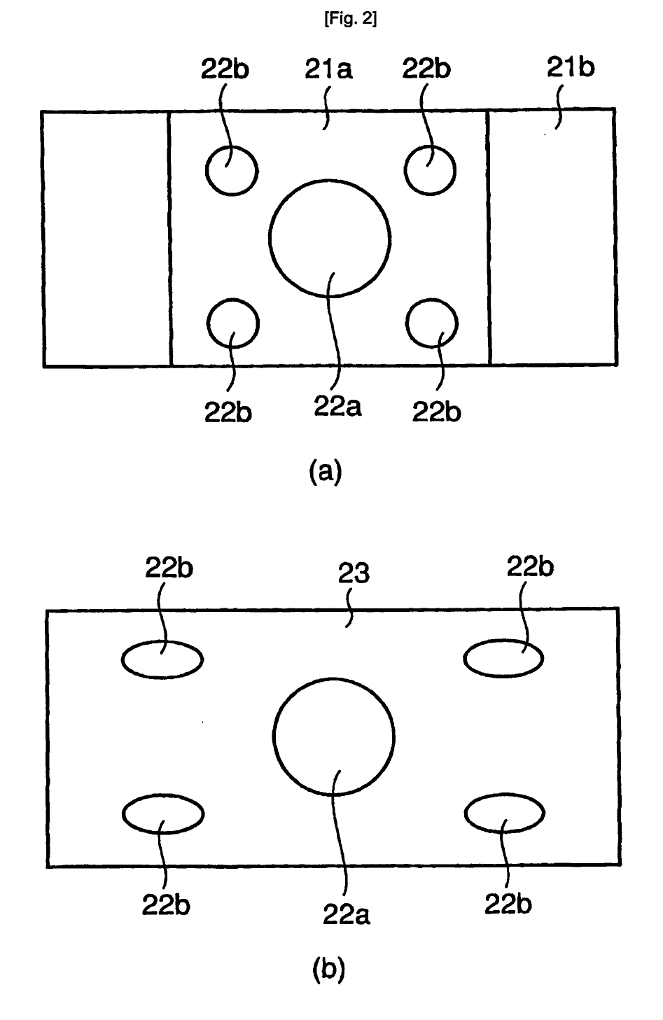

The A/D converter 11 performs sampling on the received analogue picture signal using a variable clock and performs A/D conversion. As shown in FIG. 2(b), this variable clock corresponds to the variable scanning rate when only the side part 22b is extended horizontally while the central part 22a is not extended. That is, as shown in FIG. 5(a),this variable clock has higher clock frequencies in the side part and lower clock frequencies at both ends including the central part. This allows even a non-linear displaying process to follow a variable scanning rate without using time conversion process. In this case, since the clock frequency in the side part to be extended is increased, it is possible to make the display quality of the entire screen uniform even when the side part is extended.

The data smoothing means 12 performs a smoothing process on the A/D converted picture signal using the constant frequency clock shown in FIG. 5(b). This allows nonlinear data process at a constant rate in subsequent processes.

The picture signal subjected to the data smoothing process is subjected to separation of luminance signal /chroma signal at the luminance signal extracting means 13 and chroma signal extracting means 14. In the extraction of the luminance signal at the luminance signal extracting means 13, the cutoff frequency of the low pass filter of the picture is changed according to the clock difference information. This makes it possible to perform the most suitable filtering corresponding to the sampling rate.

The luminance signal is subjected to an edge enhancement process at the edge enhancement means 15. In the edge enhancement process, parameters are changed according to the clock difference information. This allows the edge enhancement process corresponding to the sampling rate to be performed.

On the other hand, the chroma signal is decoded into a baseband signal at the chroma decoding means 16. Using the clock difference information in the decoding process, it is possible to stably reproduce the chroma modulation reference frequency of the chroma signal frequency-converted on the time axis and perform a stable decoding process.

Then, the luminance signal subjected to the edge enhancement process and the chroma-decoded color signal are changed in the screen size at the format means 17 and converted to a specific signal format at the display converting means 18. Conversion of a signal format is a conversion depending on the display device and refers to, for example, the conversion to RGB when the display device is a CRT, or the pixel conversion corresponding to the panel size of a PDP when the display device is a PDP.

Then, the picture signal processed in this way is sent to the display device and displayed on the display device. Here, since the screen size conversion in the non-linear displaying process has been already performed, the screen size need not be changed.

Then, a case where the device automatically performs panoramic non-linear displaying will be explained.

When a 4:3 analogue picture signal is received and the screen size recognition means 182 of the display converting means 18 recognizes it as the screen size of 4:3, the screen size recognition means 182 sends a control signal indicating that a non-linear displaying process is necessary to the clock change instruction means 183. When it receives the control signal, the clock change instruction means 183 sends an instruction for making the clock variable to the clock generation means 185 and the difference calculating means 184.

In response to the instruction of the clock change instruction means 183, the clock generating means 185 generates a variable clock shown in FIG. 5(a) and outputs this clock to the A/D converter 11. Furthermore, the clock generating means 185 generates a constant frequency clock shown in FIG. 5(b) and outputs this clock to the data smoothing means 12.

In response to the instruction of the clock change instruction means 183, the difference calculating means 184 calculates the difference between the variable clock generated at the clock generation means 185 and the constant frequency clock and outputs the difference information to the luminance signal extracting means 13, the edge enhancement means 15 and the chroma decoding means 16.

The subsequent processes from A/D conversion to display conversion are the same as those when panoramic non-linear display is performed by instructions from the user.

The present invention is not limited to the above described embodiment, but can be implemented modified in various manners. For example, the above described embodiment has described the case where a variable clock for sampling an analogue signal corresponding to a scanning rate has higher clock frequencies in the side part and lower clock frequencies at both ends including the central part as shown in FIG. 5(a), but the present invention is not limited to such a variable clock if it is possible to eliminate the need for a time conversion process using a variable clock for sampling an analogue signal corresponding to a scanning rate.

Furthermore, the above described has described the case where an analogue picture signal in the screen size of 4:3 is displayed in the screen size of 16:9, but the present invention is not limited to this screen size and can use any screen size which at least requires a non-linear displaying process.

Furthermore, the picture display device according to the present invention may also be connected to the display device as an independent body or may be incorporated in the display device. The display device is not limited to a liquid crystal display device or a plasma display device, but can be any light-emitting type or light receiving type of display devices capable of displaying pictures.

As described above, the picture display device according to the present invention performs sampling on an analogue signal according to a scanning rate, and can thereby respond to a variable scanning rate without using time conversion process. Thus, the present invention requires no large scale circuit, can realize conversion in screen size in a nonlinear process quite simply and improve the display quality.

### Industrial Applicability

The present invention is effectively applicable to a picture display device processing an analogue picture signal into a digital signal and displaying the digital signal such as a liquid crystal display device (LCD), a plasma display device (PDP) or an electroluminescence (EL) display device.

1. A picture display device displaying a picture using an analogue picture signal including a luminance signal and a chroma signal, comprising:
clock generating means for generating a variable clock for changing a sampling rate of said analogue picture signal depending on a scanning rate in displaying said analogue picture signal on a display device;
an A/D converter for A/D converting said analogue picture signal by sampling with said variable clock;
signal separating means for separating the A/D converted picture signal into an A/D converted luminance signal and an A/D converted chroma signal;
decoding means for decoding said A/D converted chroma signal; and
signal format converting means for a signal format conversion for said display device by using said A/D converted luminance signal and the decoded color signal.

2. A picture display device as claimed in claim 1, wherein said clock generating means generates a constant frequency clock and comprising smoothing means for smoothing the A/D converted picture signal with said constant frequency clock.

3. A picture display device as claimed in claim 2, further comprising difference calculating means for obtaining difference information between said variable clock and said constant frequency clock generated by said clock generating means.

4. A picture display device as claimed in claim 1, further comprising edge enhancement means for performing edge enhancement process to said luminance signal.

5. A picture display device as claimed in claim 3, wherein said signal separating means, said edge enhancement means and said decoding means perform signal separating process, edge enhancement process and decoding process by using said difference information respectively.

6. A picture display device as claimed in claim 1, further comprising screen size recognition means for recognizing a screen size of said analogue picture signal from said analogue picture signal.

7. A picture display device as claimed in claim 1, wherein non-linear display in the horizontal direction is performed by changing a sampling rate of said analogue picture signal depending on a scanning rate in displaying said analogue picture signal on a display device.

8. A picture display device as claimed in claim 1, wherein said display device is device selected from a group of a liquid crystal display device, a plasma display device and an electro-luminescence display device.
